(19) United States
(12) Patent Application Publication
(10) Pub. No.: US 2025/0211276 A1
(43) Pub. Date: Jun. 26, 2025

(54) PHASED ARRAY ANTENNA

(71) Applicants: STMicroelectronics France, Montrouge (FR); CENTRE NATIONAL DE LA RECHERCHE SCIENTIFIQUE, Paris (FR); INSTITUT POLYTECHNIQUE DE BORDEAUX, Talence (FR); UNIVERSITE DE BORDEAUX, Bordeaux (FR)

(72) Inventors: Thomas Capelli, Plateau D'Hauteville (FR); Philippe Cathelin, Laval (FR); Nathalie Deltimple, Pessac (FR); Anthony Ghiotto, Begles (FR)

(21) Appl. No.: 18/850,378

(22) PCT Filed: Mar. 25, 2022
(86) PCT No.: PCT/FR2022/050560

§ 371 Date: Sep. 24, 2024

(51) Int. Cl. H04B 1/38; H01Q 3/26; H03F 1/32; H03F 3/45

(52) U.S. Cl. CPC H04B 1/38; H03F 1/3211; H03F 3/45201; H01Q 3/26; H03F 2200/451

(57) ABSTRACT

According to one aspect, a phased array antenna includes a plurality of elementary antennas, and an amplifier circuit for each elementary antenna. The amplifier circuit includes a power amplifier configured to amplify at least two useful signals of different frequencies to be transmitted by the elementary antenna, a third-order intermodulation product control circuit configured to control a phase of third-order intermodulation products generated by the amplifier circuit so as to control an orientation of a radiation of the third-order intermodulation products transmitted by the phased array antenna.

### CROSS-REFERENCE TO RELATED APPLICATIONS

This application is a national stage application of International Application No. PCT/FR2022/050560, filed on Mar. 25, 2022, which application is hereby incorporated herein by reference.

### TECHNICAL FIELD

Implementations and embodiments relate to phased array antennas and methods.

### BACKGROUND

A phased array antenna includes a matrix of elementary antennas whereon signals the phase of which is adjusted according to the various elementary antennas are applied so as to obtain a desired radiation pattern for the entire phased array antenna. A phased array antenna is thus configured to perform beamforming making it possible to transmit directional beams by adapting the phase of the signals feeding the elementary antennas.

The elementary antennas are controlled by radio frequency power amplifiers. These radio frequency power amplifiers are configured to amplify a low-power radio frequency signal into a higher power signal.

Phased array antennas may be used to communicate with various types of users. For example, phased array antennas may communicate with mobile phones, vehicles, connected objects, moving satellites, etc. Phased array antennas may be configured to communicate according to fifth generation (5G) standards.

### SUMMARY

In order to communicate with a plurality of user devices, the phased array antenna is configured to generate a plurality of simultaneous beams directed towards the various devices.

In particular, the power amplifiers are configured to generate a plurality of useful signals intended for various users. When a power amplifier generates a plurality of useful signals, it also generates interfering signals.

For example, if the power amplifier generates two useful signals of different frequencies f1 and f2, it also generates third-order intermodulation products. These third-order intermodulation products are subsequently radiated by the phased array antenna.

The radiated third-order intermodulation products may be present in a bandwidth of the devices of the users. The third-order intermodulation products may thus come to interfere with an existing communication with the phased array antenna or a communication that is not even initiated by the phased array antenna generating third-order intermodulation products.

For example, FIG. 1 illustrates an example of radiations of a phased array antenna PANT. Here, the phased array antenna PANT generates beams BM1 and BM2 corresponding to two useful signals intended respectively for two users U1, U2. The beam BM1 is for example directed according to an angle θtone in relation to a main orientation of the phased array antenna.

The phased array antenna PANT also transmits beams IBM1, IBM2 corresponding to the third-order intermodulation products generated by the power amplifier of the phased array antenna PANT. Here, the beam IBM1 is oriented towards another user U3. The third-order intermodulation products may then interfere with the communications of this other user U3.

The third-order intermodulation products are on frequencies close to the frequencies of the useful signals. The third-order intermodulation products therefore may not be filtered easily.

Pre-distortion and linearization techniques may be implemented to reduce the third-order intermodulation products. Nevertheless, these techniques are expensive to implement, occupy a large amount of space in the electronic circuits of the antenna and are energy consuming.

Therefore, there is a need to propose a simple, low-cost and low energy-consuming solution that makes it possible to reduce the impact of third-order intermodulation products.

According to one aspect, a phased array antenna is proposed comprising:
a plurality of elementary antennas,
an amplifier circuit for each elementary antenna, the amplifier circuit including:
   a power amplifier configured to amplify at least two useful signals of different frequencies to be transmitted by the elementary antenna,
   a third-order intermodulation product control circuit configured to control a phase of the third-order intermodulation products generated by the amplifier circuit so as to control an orientation of a radiation of the third-order intermodulation products transmitted by the phased array antenna.

By controlling the orientation of the radiation of the third-order intermodulation products, the amplifier circuit makes it possible to perform a spatial filtering of the third-order intermodulation products.

Such an amplifier circuit thus makes it possible to reduce the impact of third-order intermodulation products that may be generated by the power amplifier.

Such an amplifier circuit therefore makes it possible to reduce, or even prevent, an interference of the communications of third-party devices. Furthermore, the third-order intermodulation product control circuit has the advantage of consuming little energy.

In an advantageous embodiment, the third-order intermodulation product control circuit comprises:
a second-order harmonic injection circuit configured to receive as input the useful signals and deliver as output a second-order harmonic signal from the useful signals, the harmonic injection circuit being adapted to be connected as output to the output of the power amplifier so as to be able to combine the signal amplified by the power amplifier and the signal delivered by the second-order harmonic injection circuit before transmitting the combined signal to the elementary antenna,
a phase controller configured to be able to adapt the phase of the signal delivered by the second-order harmonic injection circuit.

Acting on the second-order harmonics makes it possible to generate third-order intermodulation products without impacting the useful signals.

Such a third-order intermodulation product control circuit is not very expensive, consumes little energy and occupies a relatively small space in the amplifier circuit.

Preferably, the power amplifier is a differential amplifier.

Advantageously, the second-order harmonic injection circuit includes two push-push differential amplifiers.

Preferably, the differential power amplifier includes two cascodes configured to amplify the at least two useful signals of different frequencies to be transmitted by the elementary antenna. Advantageously, the second-order harmonic injection circuit includes a first push-push differential amplifier comprising two cascodes connected as output to an output of a first cascode of the differential power amplifier and a second push-push differential amplifier comprising two other cascodes connected as output to an output of the second cascode of the differential power amplifier, the first push-push differential amplifier and the second push-push differential amplifier being configured to receive the at least two useful signals of different frequencies to be transmitted by the elementary antenna.

Preferably, the phase of the third-order intermodulation products is controlled so as to deviate a radiation of the intermodulation products according to an angle of a plurality of degrees in relation to its initial direction according to which the third-order intermodulation products would be transmitted without phase control of the third-order intermodulation products. The deviation angle may be determined according to the initial direction angle of the third-order intermodulation products, the number of elementary antennas and their spacing in the phased array antenna.

According to another aspect, a method for transmitting useful signals by a phased array antenna including a plurality of elementary antennas is proposed, the method including, before the transmission of at least two useful signals by each elementary antenna:
amplifying the at least two useful signals to be transmitted by each elementary antenna,
controlling the third-order intermodulation products produced by the amplification of the at least two useful signals by adapting a phase of the third-order intermodulation products so as to control an orientation of a radiation of the third-order intermodulation products transmitted during the transmission of the useful signals by the phased array antenna.

In an advantageous implementation, for each elementary antenna, the control of the third-order intermodulation products comprises:
generating a second-order harmonic signal from the useful signals to be transmitted by the array antenna and controlling a phase of the second-order harmonic signal, then
combining the useful signals amplified with the second-order harmonic signal, then
transmitting the combined signal to the elementary antenna.

In an advantageous implementation, the phase of the third-order intermodulation products is adapted so as to deviate a radiation of the intermodulation products according to an angle of a plurality of degrees in relation to an initial direction according to which the third-order intermodulation products would be transmitted without phase control of the third-order intermodulation products.

### BRIEF DESCRIPTION OF THE DRAWINGS

Other advantages and features of the invention will become apparent upon examining the detailed description of non-limiting embodiments, and from the accompanying drawings wherein:

FIG. 1 illustrates example radiations of a prior art phased array antenna;

FIG. 2 illustrates a base station configured to communicate with a user device;

FIG. 3 illustrates an embodiment amplifier circuit;

FIG. 4 illustrates orientation modification of third-order intermodulation products radiation;

FIG. 5 illustrates an embodiment of a third-order intermodulation product controller of an amplifier circuit;

FIG. 6 illustrates further details of the embodiment amplifier circuit of FIG. 5; and

FIG. 7 illustrates a method for transmitting useful signals by a phased array antenna.

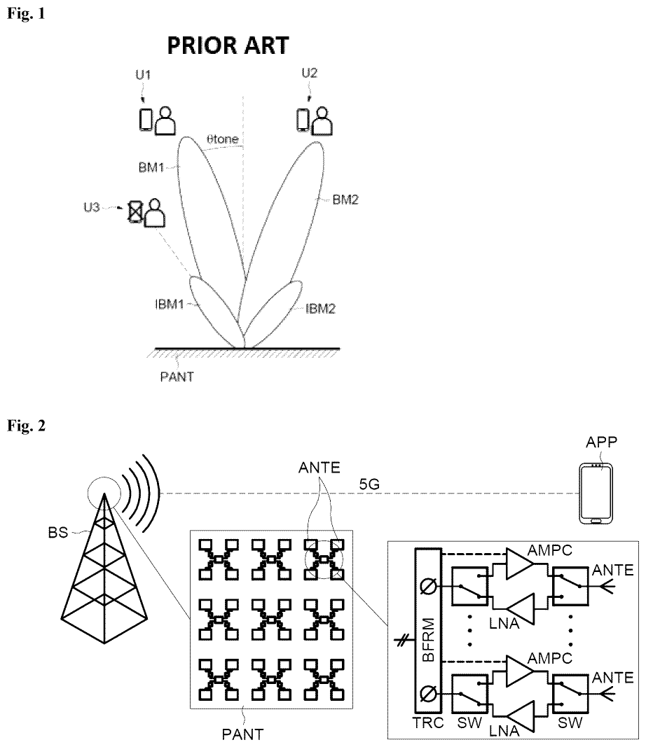

### DETAILED DESCRIPTION OF ILLUSTRATIVE EMBODIMENTS

FIG. 2 illustrates a diagram of a base station BS configured to communicate with a device APP of a user, particularly according to fifth generation 5G standards.

The base station BS includes a phased array antenna PANT. The phased array antenna PANT comprises a plurality of elementary antennas ANTE. The elementary antennas ANTE are grouped by groups of four elementary antennas ANTE. The elementary antennas ANTE of the same group are associated with the same transceiver circuit TRC.

Each transceiver circuit TRC includes a beamformer BFRM. The beamformer BFRM is used to control a phase and an amplitude of the signals to be transmitted by each elementary antenna ANTE, so as to be able to adapt the orientation of the beams radiated by the phased array antenna PANT.

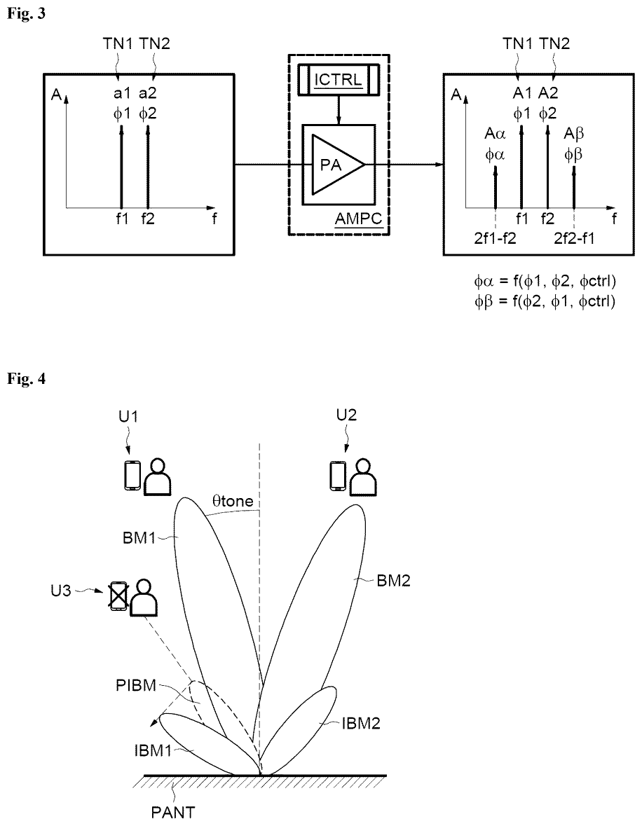

The transceiver circuit TRC also includes for each elementary antenna ANTE an amplifier circuit AMPC configured to amplify the signals to be transmitted by the elementary antenna ANTE. Such an amplifier circuit AMPC particularly includes a power amplifier PA (visible particularly in FIGS. 3, 5 and 6).

The transceiver TRC also includes for each elementary antenna ANTE a low noise amplifier LNA configured to amplify the signals received by the elementary antenna ANTE. The transceiver circuit TRC also includes switches SW making it possible to perform either a transmission or a reception.

FIG. 3 illustrates an amplifier circuit AMPC according to one embodiment.

The amplifier circuit AMPC includes a power amplifier PA configured to receive as input a two-tone signal TN1 and TN2.

The two-tone signal received as input of the power amplifier PA thus has a first tone TN1 at a frequency f1 and having a phase ϕ₁ and an amplitude a₁, and a second tone TN2 at a frequency f2 and having a phase ϕ₂ and an amplitude a₂. The power amplifier is configured to deliver as output a two-tone amplified signal.

The two-tone signal delivered as output of the power amplifier PA thus has a first tone TN1 at a frequency f1 and having a phase ϕ₁ and an amplitude A₁, greater than a₁, and a second tone TN2 at a frequency f2 and having a phase ϕ₂ and an amplitude A₂, greater than a₂.

The amplifier circuit AMPC further comprises a third-order intermodulation product controller ICTRL. The third-order intermodulation product controller ICTRL is configured to modify the orientation of the beams of the third-order intermodulation products and/or the amplitude of the third-order intermodulation products.

In particular, as illustrated in the radiation diagram shown in FIG. 4, the amplifier circuit AMPC makes it possible to modify the orientation of the radiation IBM1 of the third-order intermodulation products by an angle θ_{ϕ} in relation to the direction of the third-order intermodulation products PIBM that could be radiated if the third-order intermodulation product controller ICTRL was not used.

To modify the orientation of the radiation of the third-order intermodulation products, the third-order intermodulation product controller ICTRL is configured to modify the phase ϕ_{ctrl} of the third-order intermodulation products.

The phase of the third-order intermodulation products is controlled so as to direct a radiation of the intermodulation products according to an angle of a plurality of degrees in relation to its initial direction. The deviation angle may be determined according to the initial direction angle of the third-order intermodulation products, the number of elementary antennas and their spacing in the phased array antenna.

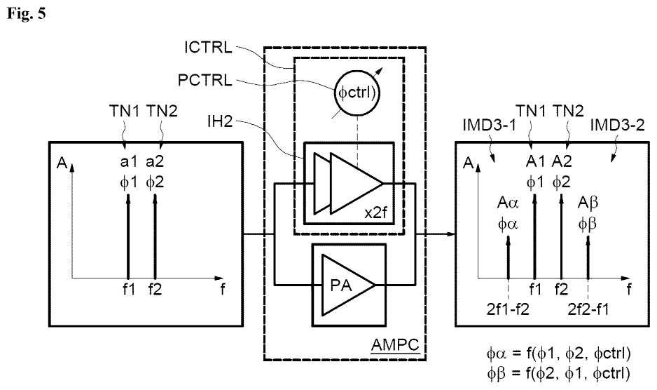

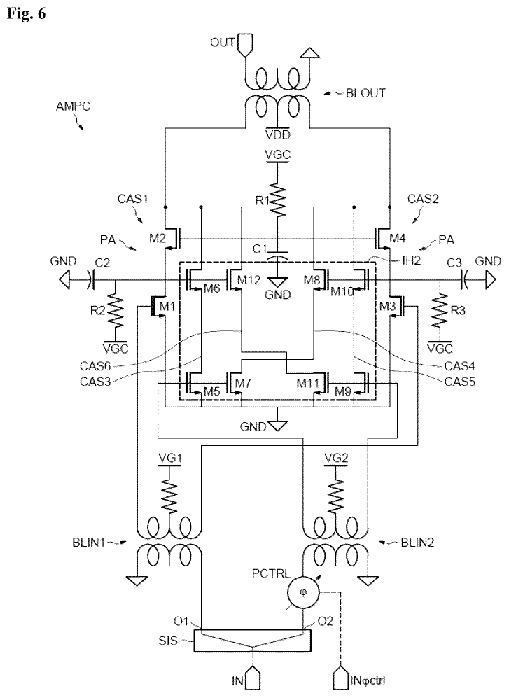

In particular, FIGS. 5 and 6 illustrate one embodiment of a third-order intermodulation product controller of an amplifier circuit AMPC.

The third-order intermodulation product controller ICTRL includes a second-order harmonic injection circuit IH2. This second-order harmonic injection circuit IH2 is configured to receive the two-tone signal as input and to generate as output a signal including second-order harmonics. The signal generated as output of the harmonic injection circuit is then on the frequencies 2f₁ and 2f₂.

The output of the second-order harmonic injection circuit IH2 is connected to the output of the power amplifier PA so as to obtain as output of the amplifier circuit AMPC a signal combining the signal amplified by the power amplifier and the signal generated by the second-order harmonic injection circuit.

The output signal of the amplifier circuit AMPC then includes the two tones TN1, TN2 of the signal amplified on the frequencies f₁ and f₂ and the third-order intermodulation products IMD3-1, IMD3-2 obtained from the second-order harmonic injection circuit IH2 on the frequencies 2f₁-f₂ and 2f₂-f₁.

The third-order intermodulation product controller PCTRL also includes a phase controller PCTRL configured to control the phase of the signals generated by the second-order harmonic injection circuit IH2.

The phases ϕ_{α} and ϕ_{β} of the third-order intermodulation products IMD3-1 and IMD3-2 then depend on the phases ϕ₁ and ϕ₂ of the two-tone signal and on the phase ϕ_{ctrl} of the signal generated by the harmonic injection circuit.

FIG. 6 illustrates an amplifier circuit AMPC according to one embodiment.

The amplifier circuit AMPC has an input IN configured to receive a two-tone signal, and an output OUT configured to deliver an amplified signal from the two-tone signal received as input.

The amplifier circuit AMPC includes a single input separator circuit SIS configured to receive as input the two-tone signal and to deliver this two-tone signal by two outputs O1, O2.

In particular, the amplifier circuit AMPC includes a first input balun BLIN1 of the asymmetric to differential type connected as input to a first output O1 of the single input separator circuit SIS.

As seen previously, the amplifier circuit AMPC includes a power amplifier PA and a second-order harmonic injection circuit IH2.

The power amplifier PA is connected to the input IN so as to be able to receive the two-tone signal by means of the input balun BLIN1 and of the single input separator circuit SIS. The power amplifier PA is connected to the output OUT so as to be able to transmit the two-tone signal by means of an output balun BLOUT of the differential-to-asymmetric type.

The power amplifier PA comprises a differential cascode of transistors of the NMOS type. The power amplifier thus includes two positive/negative amplification branches connected as input to the first input balun BLIN1, and connected as output to the output balun BLOUT.

Each amplification branch includes a cascode CAS1, CAS2 of NMOS transistors. In particular, each branch has a first transistor M1, M3 of the NMOS type and a second transistor M2, M4 of the NMOS type mounted in cascode.

These first transistors M1, M3 each include a gate controlled by the various signals delivered by the various outputs of the input balun BLIN1. The first transistor M1, M3 of each branch further includes a source connected to a cold point, particularly to a ground GND, and a drain connected to a source of the second transistor M2, M4 of the same branch.

The second transistors M2, M4 each further include a gate, the gates of the second transistors M2, M4 of each branch being connected to a first terminal of a resistive element R1. This resistive element R1 has a second terminal configured to receive a voltage V_{GC}. The first terminal of the resistive element R1 is also connected to the cold point, particularly to the ground GND, by means of a capacitive element C1.

The amplifier circuit AMPC also includes a second input balun BLIN2 of the asymmetric to differential type connected as input to a second output O2 of the single input separator circuit SIS by means of the phase controller PCTRL of the third-order intermodulation product controller ICTRL.

The phase controller PCTRL is configured to modify the phase of the signal delivered by the second output O2 of the single input separator circuit SIS. The phase applied by the phase controller is defined by the beamformer BFRM and transmitted to the phase controller by the latter by means of an input INϕ_{ctrl} of the amplifier circuit AMPC.

The second-order harmonic injection circuit IH2 includes two push-push type differential amplifiers. Each push-push amplifier includes two cascodes CAS3, CAS6, for the first and CAS4 and CAS5 for the second.

A first cascode CAS3 includes a first transistor M5 of the NMOS type having a gate connected to a first output of the second input balun BLIN2. This first transistor M5 also has a source connected to the cold point, particularly to the ground GND.

The first cascode CAS3 also includes a second transistor M6 of the NMOS type having a gate connected to a first terminal of a resistive element R2. This resistive element R2 has a second terminal configured to receive a voltage V_{GC}. The first terminal of the resistive element R2 is also connected to the cold point, particularly to the ground GND, by means of a capacitive element C2. The second transistor M6 also includes a source connected to a drain of the first transistor M5 of the same cascode CAS3.

A second cascode CAS4 includes a first transistor M7 of the NMOS type having a gate connected to a first output of the second input balun BLIN2. This first transistor M7 also has a source connected to the cold point, particularly to the ground GND.

The second cascode CAS4 also includes a second transistor M8 of the NMOS type having a gate connected to a first terminal of a resistive element R3. This resistive element R3 has a second terminal configured to receive a voltage V_{GC}. The first terminal of the resistive element R3 is also connected to the cold point, particularly to the ground GND, by means of a capacitive element C3. The second transistor M8 also includes a source connected to a drain of the first transistor M7 of the same cascode CAS4.

A third cascode CAS5 includes a first transistor M9 of the NMOS type having a gate connected to a second output of the second input balun BLIN2. This first transistor M9 also has a source connected to the cold point, particularly to the ground GND.

The third cascode CAS5 also includes a second transistor M10 of the NMOS type having a gate connected to the first terminal of the resistive element R3. The second transistor M10 also includes a source connected to a drain of the first transistor M9 of the same cascode CAS5.

A fourth cascode CAS6 includes a first transistor M11 of the NMOS type having a gate connected to a first output of the second input balun BLIN2. This first transistor also has a source connected to the cold point, particularly to the ground GND.

The fourth cascode CAS6 also includes a second transistor M12 of the NMOS type having a gate connected to the first terminal of the resistive element R2. The second transistor M12 also includes a source connected to a drain of the first transistor M11 of the same cascode CAS6.

The drains of the second transistors M6 and M12 of the first and fourth cascodes CAS3 and CAS6 of the first push-push amplifier are connected to the drain of the second transistor M2 of the cascode CAS1 of the power amplifier PA.

The drains of the second transistors M8 and M10 of the second and third cascodes CAS4 and CAS5 of the second push-push amplifier for their part are connected to the drain of the second transistor M4 of the cascode CAS2 of the power amplifier PA.

Thus, the drain currents of the power amplifier and of the push-push amplifiers are combined on the same node for each positive/negative branch.

By combining the drain currents of the power amplifier PA and of the push-push amplifiers of the second-order harmonic injection circuit IH2, the signal delivered by the output OUT includes the useful signals on the fundamental frequencies f₁ and f₂ according to the respective phases ϕ₁ and ϕ₂. The signal delivered by the output OUT also includes third-order intermodulation products IMD3-1 and IMD3-2 on the frequencies 2f₁-f₂ and 2f₂-f₁ and having for respective phases ϕ_{α} and ϕ_{β}.

As previously indicated, the phases of the intermodulation products IMD3-1 and IMD3-2 depend on the phase ϕ_{ctrl} defined by the phase controller PCTRL.

The phase controller PCTRL thus makes it possible to modify the orientation of the radiations BM1, BM2 of the third-order intermodulation products IMD3-1 and IMD3-2. The push-push amplifiers also make it possible to modify the amplitude, or even reduce it, A_{α} and A_{β} of the third-order intermodulation products IMD3-1 and IMD3-2.

The fact of acting on the second-order harmonics makes it possible to generate third-order intermodulation products IMD3-1 and IMD3-2 without impacting the useful signals.

By controlling the orientation of the radiation of the third-order intermodulation products, the amplifier circuit AMPC makes it possible to perform a spatial filtering of the third-order intermodulation products.

Such an amplifier circuit AMPC thus makes it possible to reduce the impact of third-order intermodulation products that may be generated by the power amplifier.

Such an amplifier circuit AMPC makes it possible to reduce, or even eliminate, a risk of disturbing third-party device communications.

Furthermore, such an amplifier circuit AMPC has the advantages of being not very expensive, consuming little energy and occupying a relatively small space in the phased array antenna.

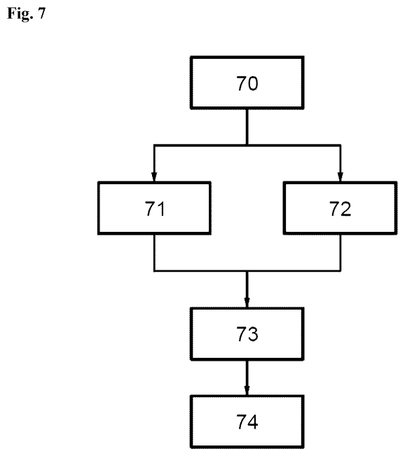

FIG. 7 illustrates one implementation of a method for transmitting useful signals by a phased array antenna such as described above. The method includes steps 70 to 74 implemented for each elementary antenna ANTE.

The method thus includes receiving 70 the useful signals to be transmitted by the amplifier circuit AMPC associated with the elementary array antenna ANTE.

The method subsequently includes amplifying 71 the useful signals received by the amplifier circuit AMPC.

At the same time, the method includes a step 72 of generating a second-order harmonic signal. In this step 72, the second-order harmonic signal is generated from the useful signals to be transmitted by the array antennas. This step 72 also includes controlling a phase of the second-order harmonic signal.

Subsequently, the method includes combining 73 the amplified useful signals with the second-order harmonic signal.

Finally, the method includes transmitting 74 the combined signal to the elementary antenna associated with the amplifier circuit in order to carry out its transmission.

1-9. (canceled)

10. A phased array antenna comprising:
a plurality of elementary antennas; and
an amplifier circuit for each elementary antenna, the amplifier circuit including:
a power amplifier configured to amplify at least two useful signals of different frequencies to be transmitted by the elementary antenna; and
a third-order intermodulation product control circuit configured to control a phase of third-order intermodulation products generated by the power amplifier amplifying the at least two useful signals, so as to control an orientation of a radiation of the third-order intermodulation products transmitted by the phased array antenna during transmission of the at least two useful signals.

11. The phased array antenna according to claim 10, wherein the third-order intermodulation product control circuit comprises:
a second-order harmonic injection circuit connected to an output of the power amplifier, and configured to:
receive as input the at least two useful signals;
generate a second-order harmonic signal from the at least two useful signals;
combine the at least two useful signals amplified with the second-order harmonic signal into a combined signal; and
transmit the combined signal to the respective elementary antenna; and
a phase controller configured to control a phase of the second-order harmonic signal generated by the second-order harmonic injection circuit.

12. The phased array antenna according to claim 11, wherein the power amplifier is a differential power amplifier.

13. The phased array antenna according to claim 12, wherein the second-order harmonic injection circuit includes first and second push-push differential amplifiers.

14. The phased array antenna according to claim 12, wherein:
the differential power amplifier includes first and second cascodes configured to amplify the at least two useful signals of different frequencies to be transmitted by the respective elementary antenna; and
the second-order harmonic injection circuit includes:
a first push-push differential amplifier comprising third and fourth cascodes connected as output to an output of the first cascode of the differential power amplifier; and
a second push-push differential amplifier comprising fifth and sixth cascodes connected as output to an output of the second cascode of the differential power amplifier;
wherein the first push-push differential amplifier and the second push-push differential amplifier are configured to receive the at least two useful signals of different frequencies to be transmitted by the respective elementary antenna.

15. The phased array antenna according to claim 10, wherein the phase of the third-order intermodulation products is controlled so as to deviate the radiation of the intermodulation products according to an angle of a plurality of degrees in relation to an initial direction according to which the third-order intermodulation products would be transmitted without phase control of the third-order intermodulation products.

16. A method of operating a phased array antenna including a plurality of elementary antennas, the method comprising:
amplifying, by a power amplifier of an amplifier circuit, at least two useful signals of different frequencies to be transmitted by each elementary antenna; and
controlling, by a third-order intermodulation product control circuit of the amplifier circuit, a phase of third-order intermodulation products generated by the amplifying of the at least two useful signals, so as to control an orientation of a radiation of the third-order intermodulation products transmitted by the phased array antenna during transmission of the at least two useful signals.

17. The method according to claim 16, wherein controlling the phase of the third-order intermodulation products comprises directing the radiation of the third-order intermodulation products according to an angle of a plurality of degrees in relation to an initial direction according to which the third-order intermodulation products would be transmitted without phase control of the third-order intermodulation products.

18. The method according to claim 16, wherein for each elementary antenna, the controlling of the phase of the third-order intermodulation products comprises:
generating, by a second-order harmonic injection circuit, a second-order harmonic signal from the at least two useful signals to be transmitted by the phased array antenna;
controlling, by a phase controller, a phase of the second-order harmonic signal;
combining, by the second-order harmonic injection circuit, the at least two useful signals amplified with the second-order harmonic signal into a combined signal; and
transmitting, by the second-order harmonic injection circuit, the combined signal to the respective elementary antenna.

19. The method according to claim 18, further comprising transmitting the at least two useful signals by each elementary antenna.

20. The method according to claim 19, wherein the power amplifier is a differential power amplifier.

21. The method according to claim 20, wherein the second-order harmonic injection circuit includes first and second push-push differential amplifiers.

22. The method according to claim 20, wherein:
amplifying, by first and second cascodes of the differential power amplifier, the at least two useful signals of different frequencies to be transmitted by the respective elementary antenna; and
receiving, by first and second push-push differential amplifiers of the second-order harmonic injection circuit, the at least two useful signals of different frequencies to be transmitted by the respective elementary antenna.

23. The method according to claim 22, wherein:
receiving, by third and fourth cascodes of the first push-push differential amplifier, an output of the first cascode of the differential power amplifier; and
receiving, by fifth and sixth cascodes of the second push-push differential amplifier, an output of the second cascode of the differential power amplifier.

24. A method of operating a phased array antenna including a plurality of elementary antennas, the method comprising:
amplifying, by a power amplifier of an amplifier circuit, at least two useful signals of different frequencies to be transmitted by each elementary antenna;
controlling, by a third-order intermodulation product control circuit of the amplifier circuit, a phase of third-order intermodulation products generated by the amplifying of the at least two useful signals, the controlling comprising directing radiation of the third-order intermodulation products according to an angle of a plurality of degrees in relation to an initial direction according to which the third-order intermodulation products would be transmitted without phase control of the third-order intermodulation products.

25. The method according to claim 24, wherein for each elementary antenna, the controlling of the phase of the third-order intermodulation products comprises:
generating, by a second-order harmonic injection circuit, a second-order harmonic signal from the at least two useful signals to be transmitted by the phased array antenna;
controlling, by a phase controller, a phase of the second-order harmonic signal;
combining, by the second-order harmonic injection circuit, the at least two useful signals amplified with the second-order harmonic signal into a combined signal; and
transmitting, by the second-order harmonic injection circuit, the combined signal to the respective elementary antenna.

26. The method according to claim 25, further comprising transmitting the at least two useful signals by each elementary antenna.

27. The method according to claim 26, wherein the power amplifier is a differential power amplifier, and the second-order harmonic injection circuit includes first and second push-push differential amplifiers.

28. The method according to claim 27, wherein:
amplifying, by first and second cascodes of the differential power amplifier, the at least two useful signals of different frequencies to be transmitted by the respective elementary antenna; and
receiving, by first and second push-push differential amplifiers of the second-order harmonic injection circuit, the at least two useful signals of different frequencies to be transmitted by the respective elementary antenna.

29. The method according to claim 28, wherein:
receiving, by third and fourth cascodes of the first push-push differential amplifier, an output of the first cascode of the differential power amplifier; and
receiving, by fifth and sixth cascodes of the second push-push differential amplifier, an output of the second cascode of the differential power amplifier.
